(19) United States
(12) Patent Application Publication
(10) Pub. No.: US 2024/0421209 A1
(43) Pub. Date: Dec. 19, 2024

(54) SEMICONDUCTOR DEVICES WITH DIFFERENT GATE DIELECTRIC THICKNESSES

(71) Applicant: QUALCOMM Incorporated, San Diego, CA (US)

(72) Inventors: Shreesh NARASIMHA, Charlotte, NC (US); Yan SUN, San Diego, CA (US); Peijie FENG, San Diego, CA (US)

(21) Appl. No.: 18/334,226

(22) Filed: Jun. 13, 2023

(51) Int. Cl. H01L 29/51; H01L 21/8234; H01L 27/088; H01L 29/06; H01L 29/423; H01L 29/775

(52) U.S. Cl. CPC H01L 29/513; H01L 21/823412; H01L 21/823462; H01L 27/088; H01L 29/0673; H01L 29/42392; H01L 29/775

(57) ABSTRACT

Disclosed are semiconductor devices and fabrication methods. A semiconductor device includes a first gate structure including a first set of channels disposed along a first direction through a first gate metal, and a first set of gate dielectrics disposed between the first set of channels and the first gate metal. The first set of gate dielectrics each have a first thickness. The semiconductor device further includes a second gate structure including a second set of channels disposed along the first direction through a second gate metal, and a second set of gate dielectrics disposed between the second set of channels and the second gate metal. The second set of gate dielectrics each have a second thickness. The second thickness is greater than the first thickness and the second set of channels is less in number than the first set of channels.

### TECHNICAL FIELD

The present disclosure generally relates to semiconductor devices, and more particularly, to a semiconductor device that includes transistors having thick-gate dielectric structures and in aspects further includes transistors having thinner gate dielectric structures formed from a common wafer.

### BACKGROUND

Integrated circuit (IC) technology has achieved great strides in advancing computing capabilities through miniaturization and modification of semiconductor components such as transistors. For example, the progression of the transistors has progressed from bulk substrates and planar metal-oxide-semiconductor field-effect transistors (MOSFETs), to three-dimensional stacking transistors such as fin field-effect transistors (FinFETs) or gate-all-around (GAA) transistors (e.g., nanowire field-effect transistors (FETs) or nanosheet FETs). Also, the technology nodes of semiconductor manufacturing processes have evolved from 14 nanometers (nm), 10 nm, 7 nm, to 3 nm and beyond.

In conventional semiconductor manufacturing processes, it is difficult to make thick-gate dielectric devices using GAA technology. In GAA, there is limited space between nanosheets (vertically), where transition layer oxide, high-K dielectric, and work-function metal is filled in to produce multi-Vt devices. The primary goal of logic scaling is to minimize the vertical spacing for logic devices to minimize the parasitic capacitance between gate and the source/drain epitaxial (S/D EPI) region across the inner spacer. In contrast, high-voltage devices (e.g., input/output (IO) devices) benefit from a thick-gate dielectric and therefore require more vertical space in the GAA structure. However, in conventional designs, the space increase required by the IO devices will cause unwanted parasitic capacitance to increase in the logic devices.

To minimize the process conflicts, high-voltage (thick-gate dielectric) devices are typically not offered in advanced GAA technologies and only thin-gate or core devices are offered due to the process conflict. Accordingly, design complexity is increased.

Therefore, there is a need for systems, apparatuses and methods that overcome the deficiencies of conventional GAA device fabrication including the methods, systems and apparatuses provided herein in the following disclosure.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

At least one aspect includes an apparatus comprising a semiconductor device wherein the semiconductor device comprises: a first gate structure including a first set of channels disposed along a first direction through a first gate metal, and a first set of gate dielectrics disposed between the first set of channels and the first gate metal, wherein the first set of gate dielectrics each have a first thickness; and a second gate structure including a second set of channels disposed along the first direction through a second gate metal, and a second set of gate dielectrics disposed between the second set of channels and the second gate metal, wherein the second set of gate dielectrics each have a second thickness, wherein the second thickness is greater than the first thickness, and wherein the second set of channels is less in number than the first set of channels.

At least one aspect includes a method of manufacturing a semiconductor device including forming a first gate structure including a first set of channels disposed along a first direction through a first gate metal, and a first set of gate dielectrics disposed between the first set of channels and the first gate metal, wherein the first set of gate dielectrics each have a first thickness; and forming a second gate structure including a second set of channels disposed along the first direction through a second gate metal, and a second set of gate dielectrics disposed between the second set of channels and the second gate metal, wherein the second set of gate dielectrics each have a second thickness, wherein the second thickness is greater than the first thickness, and wherein the second set of channels is less in number than the first set of channels.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 illustrates a partial view of a semiconductor device including a nanosheet FET, according to aspects of the disclosure.

FIG. 2 illustrates a partial view of a semiconductor device including a nanosheet FET, according to aspects of the disclosure.

FIG. 3A illustrates a plan view of a semiconductor device, according to aspects of the disclosure.

FIG. 3B illustrates a plan view of a semiconductor device, according to aspects of the disclosure.

FIG. 4A illustrates a cross-sectional view of semiconductor devices including nanosheet FETs, according to aspects of the disclosure.

FIG. 4B illustrates a cross-sectional view of semiconductor devices including nanosheet FETs, according to aspects of the disclosure.

FIGS. 5A-5K illustrate an example partial method for manufacturing a semiconductor device, according to aspects of the disclosure.

FIGS. 6A-6I illustrate an example partial method for manufacturing a semiconductor device, according to aspects of the disclosure.

FIG. 7 illustrates a method for manufacturing a semiconductor device, according to aspects of the disclosure.

FIG. 8 illustrates a mobile device example, according to aspects of the disclosure.

FIG. 9 illustrates various electronic devices that may be integrated with ICs, according to aspects of the disclosure.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage, or mode of operation.

In certain described example implementations, instances are identified where various component structures and portions of operations can be taken from known, conventional techniques, and then arranged in accordance with one or more aspects. In such instances, internal details of the known, conventional component structures and/or portions of operations may be omitted to help avoid potential obfuscation of the concepts illustrated in the illustrative aspects disclosed herein.

The terminology used herein is for the purpose of describing particular aspects only and is not intended to be limiting. As used herein, the singular forms “a,” “an,” and “the” are intended to include the plural forms as well, unless the context clearly indicates otherwise. It will be further understood that the terms “comprises.” “comprising.” “includes,” and/or “including.” when used herein, specify the presence of stated features, integers, steps, operations, elements, and/or components, but do not preclude the presence or addition of one or more other features, integers, steps, operations, elements, components, and/or groups thereof.

Particular aspects of the subject matter described in this disclosure can be implemented to realize one or more of the following potential advantages. The various aspects relate generally to semiconductor devices including thick-gate dielectric devices. According to aspects of the disclosure, low-cost masks and some additional process steps can be used to create an area on the same wafer with a modified starting heterostructure (specifically thicker silicon germanium (SiGe) dummy layers with fewer silicon (Si) layers). The various aspects disclosed provide more space (in selected regions) to form a high-voltage thick gate dielectric device for IO or other high-voltage applications while simultaneously preserving the low capacitance structure for the core logic. Accordingly, the processes for the formation of the logic device region are not disrupted and the parasitic capacitance of the logic (or core) devices are not affected. Further, no new material is used. These and other advantages and alternatives will be appreciated from the following disclosure, associated figures, and claims.

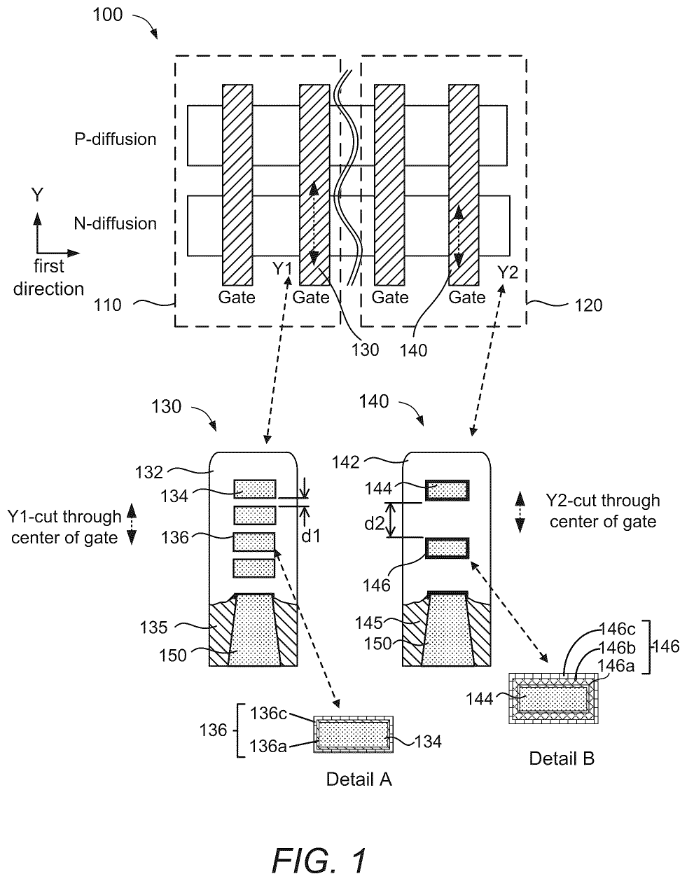

FIG. 1 illustrates a portion of a semiconductor device 100 including GAA devices, according to aspects of the disclosure. In some aspects, the semiconductor device 100 may be a die or an IC or portion thereof. A simplified example of a first gate structure 130 in a first region 110 (e.g., core region) and a second gate structure 140 in a second region 120 (e.g., high-voltage region). In some aspects, other elements or configurations for the first gate structure 130 and the second gate structure 140 may be used in the various aspects, in addition to the example shown in FIG. 1. Accordingly, the various aspects disclosed and claimed are not limited to the specific example illustrations provided herein.

As shown in FIG. 1, the semiconductor device 100 includes the first gate structure 130 having a first set of channels 134 disposed along a first direction through a first gate metal 132. In some aspects, the first gate metal 132 comprises Tungsten (W), Titanium Nitride (TiN), or Titanium aluminide (TiAl). A first set of gate dielectrics 136 is disposed between the first set of channels 134 and the first gate metal 132. The first set of gate dielectrics 136 each have a first thickness. The second gate structure 140 includes a second set of channels 144 disposed along the first direction through a second gate metal 142, and a second set of gate dielectrics 146 disposed between the second set of channels 144 and the second gate metal 142. In some aspects, the second gate metal 142 comprises Tungsten (W), Titanium Nitride (TiN), or Titanium aluminide (TiAl). The second set of gate dielectrics 146 each have a second thickness which is greater than the first thickness. As discussed herein, the thickness of the second set of gate dielectrics 146 allows the devices in the second region to operate at higher voltages than the devices in the first region with the thinner first set of gate dielectrics. Additionally, the thinner first set of gate dielectrics allow for reduced vertical spacing for logic devices and to minimize the parasitic capacitance, as discussed herein.

In some aspects, the first thickness of the first set of gate dielectrics 136, is in a range of 0.8 to 1.5 nanometers (nm). In some aspects, the second thickness of the second set of gate dielectrics 146, is in a range of 2.5 to 3.5 nm. In some aspects, the second set of gate dielectrics 146 each have at least one additional dielectric layer than the first set of gate dielectrics. In some aspects, the at least one additional dielectric layer is a different material than other dielectric layers of the second set of gate dielectrics. As used herein the term “thickness” of the gate dielectric can be considered an equivalent oxide thickness (EOT) to compare gate dielectric thickness. For example, although illustrated as a unitary layer for convenience, it will be appreciated that the gate dielectric EOT can be formed from multiple layers and/or materials. For example, as illustrated in Detail A, the first set of gate dielectrics 136 can be formed from an interfacial oxide layer 136a, (e.g., silicon dioxide) adjacent the channel 134 and a high dielectric constant (high-K) dielectric 136c (e.g., hafnium dioxide) adjacent the gate metal 132. It will be appreciated that materials with a dielectric constant greater than 3.9 can be considered high-K. Further, as illustrated in Detail B, the second set of gate dielectrics 146 can be formed from an interfacial oxide layer 146a. (e.g., thin silicon dioxide layer formed from thermal oxidation of the silicon channel) adjacent the channel 144, a middle dielectric layer 146b, (e.g., nitridated silicon dioxide) which is thicker than interfacial oxide layer 146a and is disposed between the interfacial oxide layer 146a and the high-K dielectric 146c. In some aspects, the interfacial oxide layer 146a and interfacial oxide layer 136a may be formed at the same time, be the same material and have a similar thickness. In some aspects, the high-K dielectric 146c and high-K dielectric 136c may be formed at the same time be the same material and have a similar thickness. Accordingly, additional process steps will be avoided. It will be appreciated that the foregoing examples are provided merely to aid in the explanation of the various aspects. The various aspects disclosed and claimed are not limited to the materials and/or layer configurations illustrated. For example, in some aspects the high-K dielectric 146c could be made thicker or additional dielectric layers can be added to provide for the increased EOT for the second set of gate dielectrics 146. Accordingly, in the remaining description, the term “thickness” will be used for the gate dielectrics and the gate dielectrics generally will be described and illustrated as a single element.

Further, the second set of channels 144 is less in number than the first set of channels 134. In some aspects, the second set of channels 144 is half the number of the first set of channels 134. Additionally, as illustrated, a second distance d2 between channels of the second set of channels 144 is greater than a first distance d1 between channels of the first set of channels 134. In some aspects, the first distance d1 is in a range of 8 to 12 nanometers (nm). In some aspects, the second distance d2 is in a range of 20 to 28 nm. In some aspects, the first channel (top channel) of the first set of channels 134 and a second channel (top channel) of the second set of channels 144 are coplanar along the first direction. In some aspects, each channel of the second set of channels 144 is coplanar in the first direction with a corresponding channel of the first set of channels 134. In some aspects, the first set of channels 134 and the second set of channels 144 are nanosheets or nanoribbons and form part of a GAA device.

As can be seen in FIG. 1, the first gate structure 130 and the second gate structure 140 are disposed on a substrate 150, which in some aspects may be Silicon (Si) and may extend to the gate metal being insulated by a portion of the gate dielectrics 136 and 146 and isolation structures 135 and 145, respectively. In some aspects, the isolation structures 135 and 145 may comprise SiO₂ and may be shallow trench isolation (STI) structures.

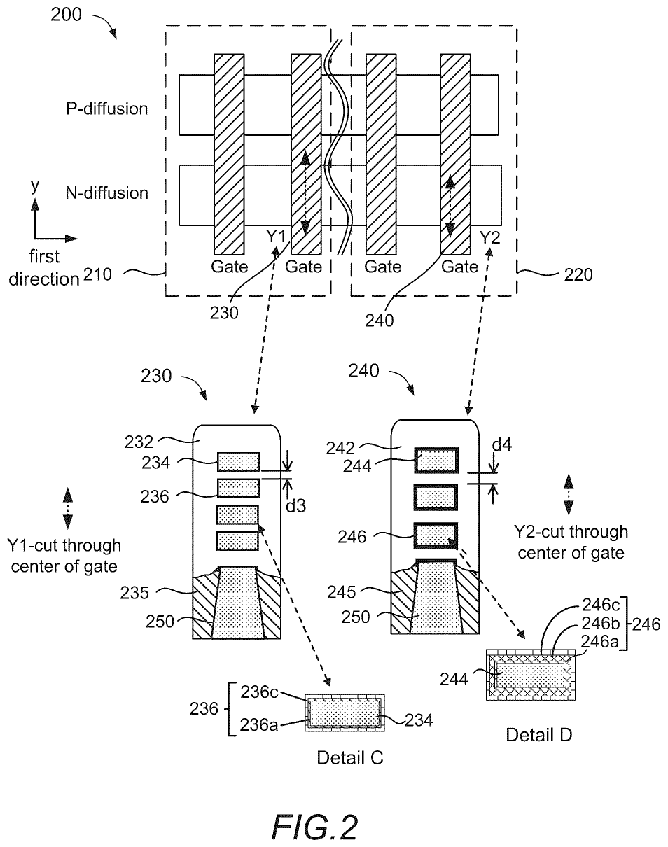

FIG. 2 illustrates a portion of a semiconductor device 200 including GAA devices, according to aspects of the disclosure. In some aspects, the semiconductor device 200 may be a die or an IC or portion thereof. A simplified example of a first gate structure 230 in a first region 210 (e.g., core region) and a second gate structure 240 in a second region 220 (e.g., high-voltage region). In some aspects, other elements, or configurations for the first gate structure 230 and the second gate structure 240 may be used in the various aspects, in addition to the example shown in FIG. 2. Accordingly, the various aspects disclosed and claimed are not limited to the specific example illustrations provided herein.

As shown in FIG. 2, the semiconductor device 200 includes the first gate structure 230 having a first set of channels 234 disposed along a first direction through a first gate metal 232. A first set of gate dielectrics 236 is disposed between the first set of channels 234 and the first gate metal 232. In some aspects, the first gate metal 232 comprises Tungsten (W), Titanium Nitride (TiN), or Titanium aluminide (TiAl). The first set of gate dielectrics 236 each have a first thickness. The second gate structure 240 includes a second set of channels 244 disposed along the first direction through a second gate metal 242, and a second set of gate dielectrics 246 disposed between the second set of channels 244 and the second gate metal 242. In some aspects, the second gate metal 232 comprises Tungsten (W), Titanium Nitride (TiN), or Titanium aluminide (TiAl). The second set of gate dielectrics 246 each have a second thickness which is greater than the first thickness. As discussed herein, the thickness of the second set of gate dielectrics 246 allows the devices in the second region to operate at higher voltages than the devices in the first region with the thinner first set of gate dielectrics 236. In some aspects, the first thickness of the first set of gate dielectrics 236 is in a range of 0.8 to 1.5 nanometers (nm). In some aspects, the second thickness of the second set of gate dielectrics 246 is in a range of 2.5 to 3.5 nm. In some aspects, the second set of gate dielectrics each have at least one additional dielectric layer than the first set of gate dielectrics. In some aspects, the at least one additional dielectric layer is a different material than other dielectric layers of the second set of gate dielectrics. As noted above, the term “thickness” of the gate dielectric can be considered an equivalent oxide thickness (EOT) to compare gate dielectric thicknesses. Additionally, although illustrated as a unitary layer for convenience, it will be appreciated that the gate dielectric EOT can be formed from multiple layers and/or materials, as described above in relation to FIG. 1. For example, as illustrated in Detail C, the first set of gate dielectrics 236 can be formed from an interfacial oxide layer 236a, (e.g., thin silicon dioxide layer formed from thermal oxidation of the silicon channel) adjacent the channel 234 and a high-K dielectric 236c (e.g., hafnium dioxide). Further, as illustrated in Detail D, the second set of gate dielectrics 246 can be formed from an interfacial oxide layer 246a. (e.g., thin silicon dioxide layer formed from thermal oxidation of the silicon channel) adjacent the channel 244, a middle dielectric layer 246b, (e.g., nitridated silicon dioxide) which is thicker than the interfacial oxide layer 246a and is disposed between the interfacial oxide layer 246a and a high-K dielectric 246c (e.g., hafnium dioxide). In some aspects, the interfacial oxide layer 236a and interfacial oxide layer 246a may be formed at the same time, be the same material and have a similar thickness. In some aspects, the high-K dielectric 246c and high-K dielectric 236c may be formed at the same time be the same material and have a similar thickness. Accordingly, additional process steps will be avoided. It will be appreciated that the foregoing examples are provided merely to aid in the explanation of the various aspects. The various aspects disclosed and claimed are not limited to the materials and/or layer configurations illustrated. For example, in some aspects the high-K dielectric 246c could be made thicker to provide for the increased EOT for the second set of gate dielectrics 246. Accordingly, in the remaining description, the term “thickness” will be used for the gate dielectrics and the gate dielectric layers will generally be described and illustrated as a single element.

Further, the second set of channels 244 is less in number than the first set of channels 234. In some aspects, the second set of channels 244 is one less than the number of the first set of channels 234 or any number that is less than the number of channels in the first set of channels 234. Additionally, as illustrated, a second distance d4 between channels of the second set of channels 244 is greater than a first distance d3 between channels of the first set of channels 234. In some aspects, the first distance d3 is in a range of 8 to 12 nanometers (nm). In some aspects, the second distance d4 is in a range of 12 to 18 nm. In some aspects, the first channel (top channel) of the first set of channels 234 and a second channel (top channel) of the second set of channels 244 are coplanar along the first direction. In some aspects, at least one channel of the second set of channels 244 is not coplanar in the first direction with any channel of the first set of channels 234. In some aspects, the first set of channels 234 and the second set of channels 244 are nanosheets or nanoribbons and form part of a GAA device.

As can be seen in FIG. 2, the first gate structure 230 and the second gate structure 240 are disposed on a substrate 250, which in some aspects may be Silicon (Si) and may extend to the gate metal being insulated by isolation structures 235 and 245 and a portion of the gate dielectrics 236 and 246. In some aspects, the isolation structures 235 and 245 may comprise SiO₂ and may be shallow trench isolation (STI) structures.

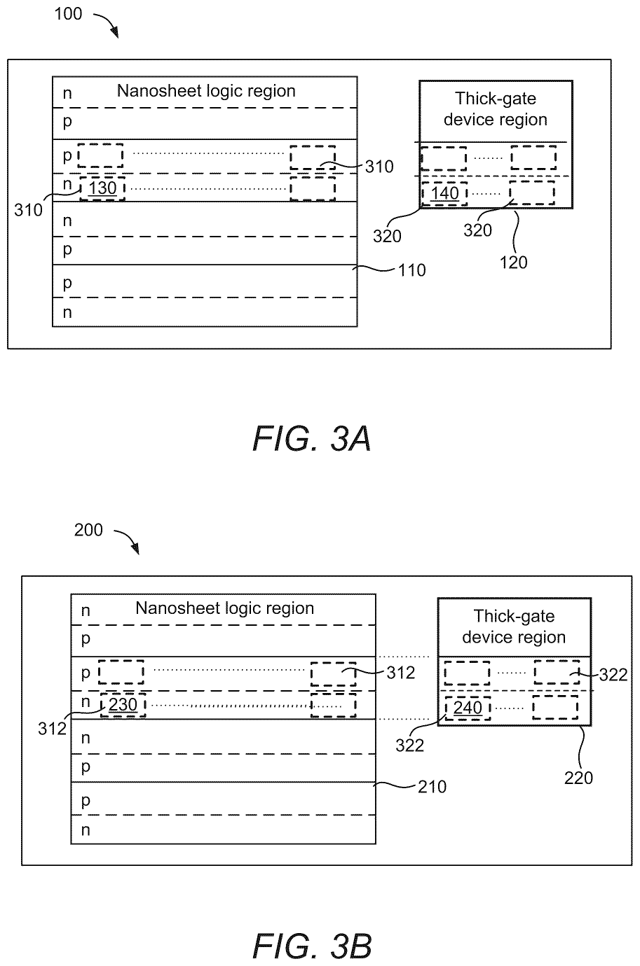

FIG. 3A illustrates a plan view of a portion of semiconductor device 100 including a plurality of GAA devices, according to aspects of the disclosure arranged in standard cell rows formed from a nanosheet wafer. The example GAA devices may be formed in the N and P diffusions regions as GAA field effect transistors (FET—e.g., NFET, PFET). In some aspects, the semiconductor device 100 may be a die or an IC or portion thereof. In some aspects, the semiconductor device 100 may include, in the first region 110, a first plurality of GAA devices 310 including thin-gate dielectric structures, such as gate structures 130, which are configured for high-speed logic and similar applications, as discussed herein. The first plurality of GAA devices 310 may include both NFET and PFET devices. In some aspects, the semiconductor device 100 may include, in the second region 120 formed from the nanosheet wafer, a second plurality of GAA devices 320 including thick-gate dielectric structures, such as second gate structures 140, which are configured for high-voltage, IO and similar applications, as discussed herein. The second plurality of GAA devices 320 may include both NFET and PFET devices. FIG. 3A is merely provided as an example layout to aid in the explanation of the various aspects disclosed. It will be appreciated that the various aspects disclosed and claimed are not limited to the specific example illustrations provided herein.

FIG. 3B illustrates a plan view of a semiconductor device 200 including a plurality of GAA devices, according to aspects of the disclosure, arranged in standard cell rows formed from a nanosheet wafer. The example GAA devices may be formed in the N and P diffusions regions as GAA field effect transistors (FET—e.g., NFET, PFET). In some aspects, the semiconductor device 200 may be a die or an IC or portion thereof. In some aspects, the semiconductor device 200 may include in the first region 210, a first plurality of GAA devices 312 including thin-gate dielectric structures, such as gate structures 230, which are configured for high-speed logic and similar applications, as discussed herein. The first plurality of GAA devices 312 may include both NFET and PFET devices. In some aspects, the semiconductor device 200 may include in the second region 220 formed from the nanosheet wafer, a second plurality of GAA devices 322 including thick-gate dielectric structures, such as second gate structures 240, which are configured for high-voltage, IO, and similar applications, as discussed herein. The second plurality of GAA devices 322 may include both NFET and PFET devices. FIG. 3B is merely provided as an example layout to aid in the explanation of the various aspects disclosed. It will be appreciated that the various aspects disclosed and claimed are not limited to the specific example illustrations provided herein.

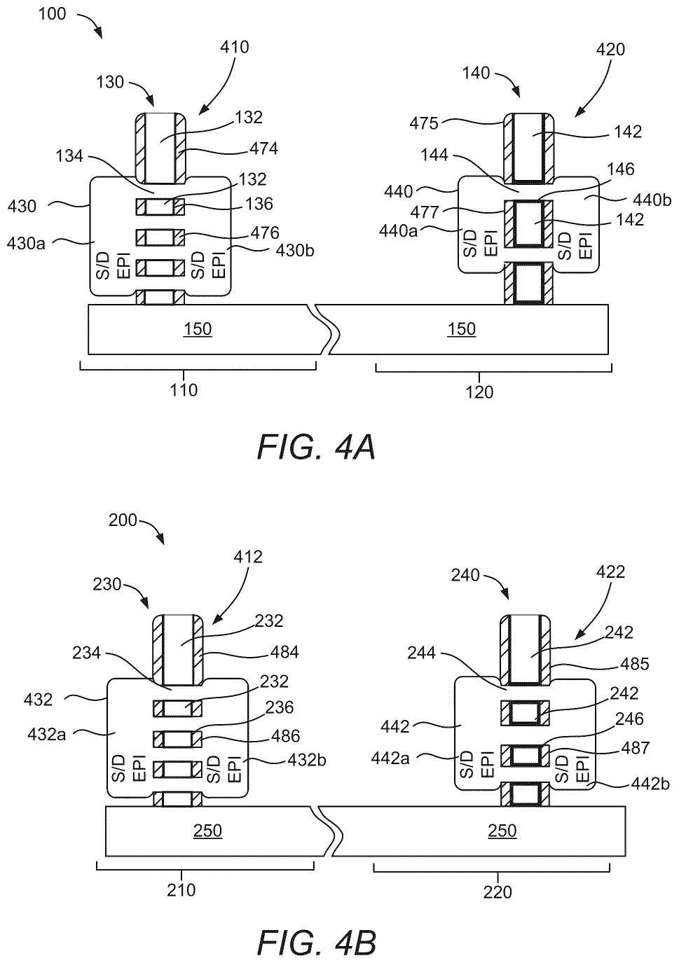

FIG. 4A illustrates a partial view of a semiconductor device 100 according to aspects of the disclosure. In some aspects, the semiconductor device 100 may include in the first region 110, a first plurality of GAA devices, similar to first GAA device 410, on substrate 150, including thin-gate dielectric structures, such as first gate structure 130, which is configured for high-speed logic and similar applications, as discussed herein. In some aspects, the first GAA device 410 may include a first source/drain epitaxial (S/D EPI) structure 430 disposed on opposite sides of the first gate structure 130 and electrically coupled to the first set of channels 134. It will be appreciated that one side of the first S/D EPI structure 430 will be configured as the source, e.g., a first source 430a and the other as the drain, e.g., a first drain 430b. It should be noted that structurally, the first source 430a and the first drain 430b may be very similar to each other. That is, either side may be configured to be used as a source and the other can be used as a drain. Therefore, the illustrated configuration should not be construed as limiting the various aspects disclosed or claimed. Accordingly, for ease of explanation and illustration the first S/D EPI structure 430 is referred herein to represent both the source and the drain. Likewise, as used herein, the term source/drain structure may be used to represent both the source and the drain. The first set of gate dielectrics 136 is disposed between the first set of channels 134 and the first gate metal 132. Additionally, first inner spacers 476 and first outer spacers 474 provide for insulation between first gate metal 132 and the first S/D EPI structure 430. It will be appreciated that additional conventional elements, such as gate and source/drain contacts, additional insulation/dielectric layers, interconnections, etc., for the first GAA device 410 are not shown for convenience and to avoid unnecessary complexity in the illustrated configuration.

In some aspects, the semiconductor device 100 may include, in the second region 120, a second plurality of GAA devices, similar to second GAA device 420, on substrate 150 including thick-gate dielectric structures, such as second gate structures 140, which are configured for high-voltage, IO and similar applications, as discussed herein. In some aspects, the second GAA devices 420 may include a second source/drain epitaxial (S/D EPI) structure 440 disposed on opposite sides of the second gate structure 140 and electrically coupled to the second set of channels 144. It will be appreciated that one side of the second S/D EPI structure 440 will be configured as the source, e.g., a second source 440a and the other as the drain, e.g., a second drain 440b. It should be noted that structurally, the second source 440a and the second drain 440b may be very similar to each other. That is, either side may be configured to be used as a source and other can be used as a drain. Therefore, the illustrated configuration should not be construed as limiting the various aspects disclosed or claimed. Accordingly, for case of explanation and illustration the second S/D EPI structure 440 is referred herein to represent both the source and the drain. The second set of gate dielectrics 146 is disposed between the second set of channels 144 and the second gate metal 142. Additionally, second inner spacers 477 and second outer spacers 475 provide for insulation between the second gate metal 142 and the second S/D EPI structure 440. It will be appreciated that additional conventional elements, such as gate and S/D contacts, additional insulation/dielectric layers, interconnections, etc., for the second GAA device 420 are not shown for convenience and to avoid unnecessary complexity in the illustrated configuration. Further. it will be appreciated that the example illustration of FIG. 4A is merely provided as an example layout to aid in the explanation of the various aspects disclosed. It will be appreciated that the various aspects disclosed and claimed are not limited to the specific example illustrations provided herein.

FIG. 4B illustrates a partial view of a semiconductor device 200 according to aspects of the disclosure. In some aspects, the semiconductor device 200 may include in the first region 210, a first plurality of GAA devices, similar to first GAA device 412, on substrate 250, including thin-gate dielectric structures, such as gate structures 230, which are configured for high-speed logic and similar applications, as discussed herein. In some aspects, the first GAA device 412 may include a first source/drain epitaxial (S/D EPI) structure 432 disposed on opposite sides of the second gate structure 240 and coupled to the first set of channels 234. It will be appreciated that one side of the first S/D EPI structure 432 will be configured as the source, e.g., a first source 432a, and the other as the drain, e.g., a first drain 432b. It should be noted that structurally, the first source 432a and the first drain 432b may be very similar to each other. That is, either side may be configured to be used as a source and other can be used as a drain. Therefore, the illustrated configuration should not be construed as limiting the various aspects disclosed or claimed. Accordingly, for ease of explanation and illustration the first S/D EPI structure 432 is referred herein to represent both the source and the drain. The first set of gate dielectrics 236 is disposed between the first set of channels 234 and the first gate metal 232. Additionally, first inner spacers 486 and first outer spacer 484 provide for insulation between first gate metal 132 and the first S/D EPI structure 432. It will be appreciated that additional conventional elements, such as gate and S/D contacts, additional insulation/dielectric layers, interconnections, etc. for the first GAA device 412 are not shown for convenience and to avoid unnecessary complexity in the illustrated configuration.

In some aspects, the semiconductor device 200 may include in the second region 220, a second plurality of GAA devices similar to second GAA device 422, on substrate 250, including thick-gate dielectric structures, such as second gate structures 240, which are configured for high-voltage, IO, and similar applications, as discussed herein. In some aspects, the second GAA device 422 may include a second source/drain epitaxial (S/D EPI) structure 442 disposed on opposite sides of the second gate structure 240 and coupled to the second set of channels 244. It will be appreciated that one side of the second S/D EPI structure 442 will be configured as the source, e.g., a second source 442a and the other as the drain, e.g., a second drain 442b. It should be noted that structurally, the second source 442a and the second drain 442b may be very similar to each other. That is, either side may be configured to be used as a source and other can be used as a drain. Therefore, the illustrated configuration should not be construed as limiting the various aspects disclosed or claimed. Accordingly, for case of explanation and illustration the second S/D EPI structure 442 is referred herein to represent both the source and the drain. The second set of gate dielectrics 246 is disposed between the second set of channels 244 and the second gate metal 242. Additionally, second inner spacers 487 and second outer spacer 485 provide for insulation between second gate metal 242 and the second S/D EPI structure 442. It will be appreciated that additional conventional elements, such as gate and S/D contacts, additional insulation/dielectric layers, interconnections, etc., for the second GAA device 422 are not shown for convenience and to avoid unnecessary complexity in the illustrated configuration. It will be appreciated that the example illustration of FIG. 4B is merely provided as an example layout to aid in the explanation of the various aspects disclosed. It will be appreciated that the various aspects disclosed and claimed are not limited to the specific example illustrations provided herein.

In order to fully illustrate aspects of the design of the present disclosure, methods of fabrication are presented. Further, many details in the fabrication process known to those skilled in the art may have been omitted or combined in summary process portions to facilitate an understanding of the various aspects disclosed without a detailed rendition of each detail and/or all possible process variations.

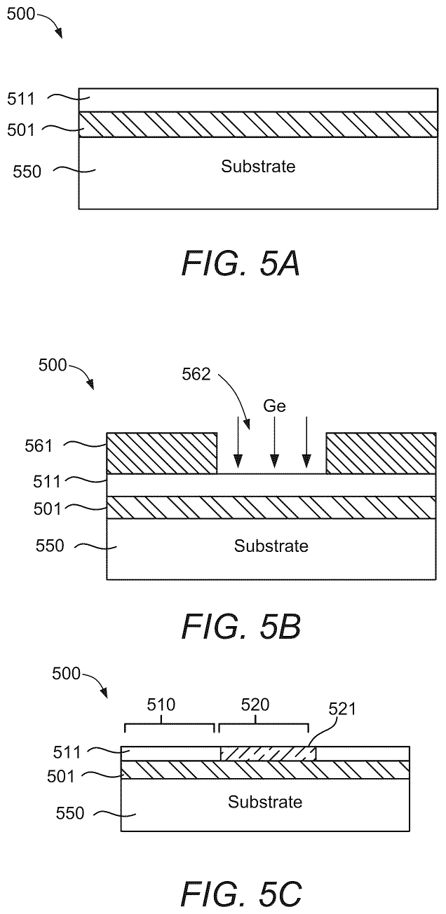

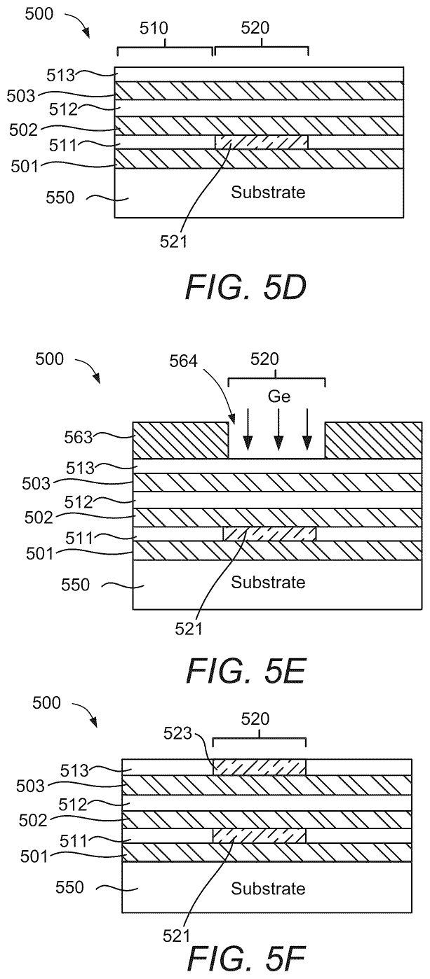

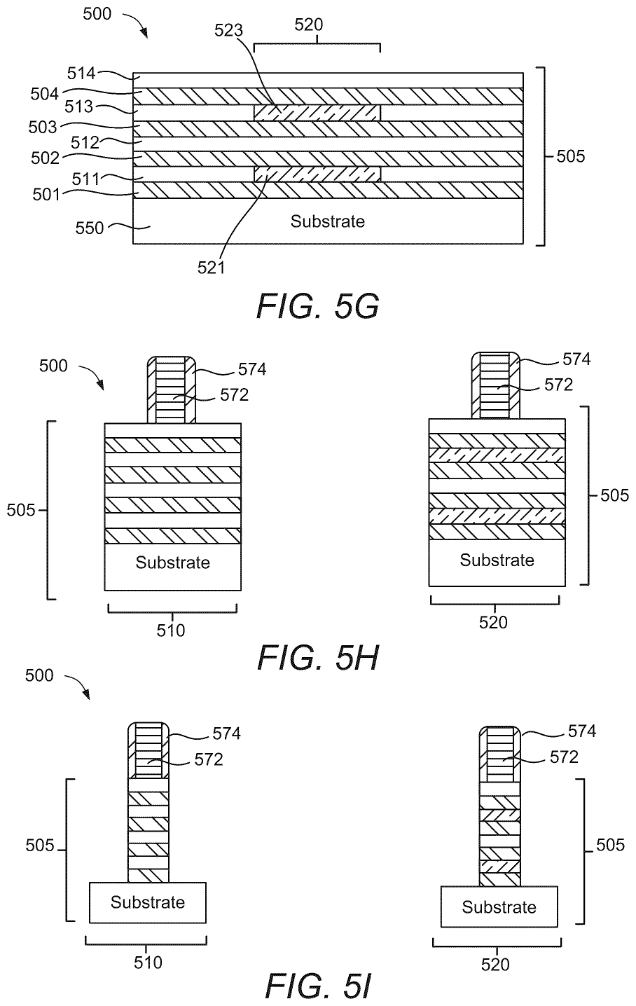

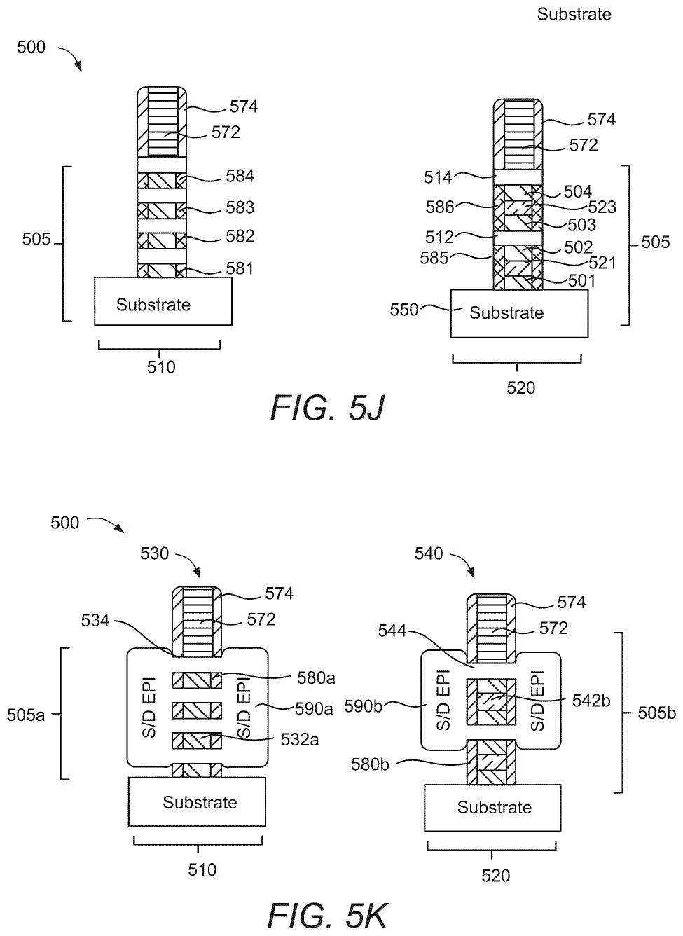

FIGS. 5A to 5K illustrate a partial method for manufacturing a semiconductor device (such as the semiconductor device 100 in FIG. 1), according to aspects of the disclosure.

As shown in FIG. 5A, a semiconductor device 500 is formed. The semiconductor device 500 includes a substrate 550 and a first sacrificial gate layer 501 on which a first nanosheet layer 511 is grown. In some aspects, the first nanosheet layer 511 is Si. In some aspects, the substrate 550 includes Si, Ge, As, or any combination thereof. In some aspects, the first sacrificial gate layer 501 may be SiGe.

As shown in FIG. 5B, the semiconductor device 500 fabrication process continues with substrate 550, the first sacrificial gate layer 501 disposed on the substrate 550 and the first nanosheet layer 511 disposed on the first sacrificial gate layer 501. At this stage of the process, a photoresist 561 is deposited and patterned to form an opening 562 to the first nanosheet layer 511. The opening is used to infuse the nanosheet layer with germanium (Ge) by implantation or other suitable processes.

As shown in FIG. 5C, the semiconductor device 500 fabrication process continues with substrate 550, the first sacrificial gate layer 501 disposed on the substrate 550 and the first nanosheet layer 511 disposed on the first sacrificial gate layer 501. At this stage of the process, the first nanosheet layer 511 is infused with germanium (Ge) forming a sacrificial portion 521 of the first nanosheet layer 511 in a second region 520. The first nanosheet layer 511 remains unchanged in the first region 510.

As shown in FIG. 5D, the semiconductor device 500 fabrication process continues with the stack including the substrate 550, the first sacrificial gate layer 501, the first nanosheet layer 511 disposed on the first sacrificial gate layer 501 having the SiGe infused sacrificial portion 521 in a second region 520 adjacent the first region 510. At this stage of the fabrication process a second sacrificial gate layer 502 is formed on the first nanosheet layer 511, a second nanosheet layer 512 is grown on the second sacrificial gate layer 502, a third sacrificial gate layer 503 is formed on the second nanosheet layer 512, and a third nanosheet layer 513 is grown on the third sacrificial gate layer 503.

As shown in FIG. 5E, the semiconductor device 500 fabrication process continues with the stack including the substrate 550, the first sacrificial gate layer 501, the first nanosheet layer 511 having the SiGe infused sacrificial portion 521 in the second region 520, the second sacrificial gate layer 502, the second nanosheet layer 512, the third sacrificial gate layer 503 and the third nanosheet layer 513. At this stage of the process, a photoresist 563 is deposited and patterned to form an opening 564 to the third nanosheet layer 513. The opening is used to infuse the third nanosheet layer 513 with germanium (Ge) in the second region 520, by implantation or other suitable processes.

As shown in FIG. 5F, the semiconductor device 500 fabrication process continues with the stack including the substrate 550, the first sacrificial gate layer 501, the first nanosheet layer 511 having the SiGe infused sacrificial portion 521 in the second region 520, the second sacrificial gate layer 502, the second nanosheet layer 512, the third sacrificial gate layer 503 and the third nanosheet layer 513. At this stage of the process, the third nanosheet layer 513 is infused with Ge forming a sacrificial portion 523 of the third nanosheet layer 513 in the second region 520. The third nanosheet layer 513 remains unchanged outside the second region 520.

As shown in FIG. 5G, the semiconductor device 500 fabrication process continues with the stack including the substrate 550, the first sacrificial gate layer 501, the first nanosheet layer 511 having the SiGe infused sacrificial portion 521 in the second region 520, the second sacrificial gate layer 502, the second nanosheet layer 512, the third sacrificial gate layer 503 and the third nanosheet layer 513 having the sacrificial portion 523 of the third nanosheet layer 513 in the second region 520. At this stage of the fabrication process a fourth sacrificial gate layer 504 is formed on the third nanosheet layer 513 and a fourth nanosheet layer 514 is grown on the fourth sacrificial gate layer 504.

The fabrication process of FIGS. 5A-5G forms the incoming nanosheet wafer 505 that is used for further processing. It will be appreciated that the incoming wafer has two distinct regions, first region 510 that has a conventional sacrificial gate layer and nanosheet layer stack and a second region that has one or more SiGe portions disposed between sacrificial gate layers that effectively form three-layer homogenous SiGe portions in the second region, which will be used in the further processing discussed below.

As shown in FIG. 5H, the semiconductor device 500 fabrication process continues with nanosheet wafer 505 having a gate polysilicon 572 and outer spacer 574 being formed for each gate structure over the nanosheet wafer 505 in both the first region 510 and the second region 520. The gate polysilicon 572 and outer spacer 574 can be formed using conventional processes in both the first region 510 and the second region 520.

As shown in FIG. 5I, the semiconductor device 500 fabrication process continues with nanosheet wafer 505 having the gate polysilicon 572 and outer spacer 574 disposed on the wafer in both the first region 510 and the second region 520. At this stage, a source/drain (S/D) recess process is performed to remove excess wafer material from the S/D regions. The source/drain (S/D) recess process may be performed using conventional fabrication processes for GAA devices.

As shown in FIG. 5J, the semiconductor device 500 fabrication process continues with nanosheet wafer 505 having the gate polysilicon 572 and outer spacer 574 disposed on the wafer in both the first region 510 and the second region 520. At this stage, the process continues with the inner spacer formation. The sacrificial gate layers of the nanosheet wafer 505 are indented to allow room for encapsulation of the sacrificial gate layers with a dielectric that forms the inner spacer. For the GAA devices in the first region 510, there are four inner spacers 581, 582, 583 and 584 formed. For the GAA devices in the second region 520, there are two inner spacers 585 and 586 formed due to the homogeneous sacrificial portions (e.g., homogeneous SiGe portions) formed by sacrificial gate layers 501 and 502 with sacrificial portion 521 for inner spacer 585 and sacrificial gate layers 503 and 504 with sacrificial portion 523 for inner spacer 586. It will be appreciated that nanosheet wafer 505 in the second region 520 has an increased height of inner spacer 585 between the substrate 550 and second nanosheet layer 512 and inner spacer 586 between nanosheet layers 512 and 514. This increased spacing provides for forming the increased gate dielectric thickness in the second region in later processing, as illustrated and discussed herein including in relation to the example aspects of FIG. 1 and FIG. 4A.

As shown in FIG. 5K, the semiconductor device 500 fabrication process continues with a first gate structure 530 in the first region 510 which includes the gate polysilicon 572 and outer spacer 574, a gate stack 505a which includes first set of channels 534 (formed from the nanosheets of the nanosheet wafer 505 discussed above) and sacrificial gate layers 532a with inner spacers 580a (which is used as simplified representations of individual inner spacers 581, 582, 583 and 584). A second gate structure 540 is in the second region 520 which includes the gate polysilicon 572 and outer spacer 574, a gate stack 505b which includes first set of channels 534 (formed from the nanosheets of the nanosheet wafer 505) and homogeneous sacrificial portions 542b with inner spacers 580b The homogeneous sacrificial portions 542b are used as simplified representations of 501, 521 and 502 and 503, 523 and 504. Likewise, inner spacers 580b are used as simplified representations of individual inner spacers 585 and 586. At this stage, the process continues with forming a first source/drain epitaxial (S/D EPI) structure 590a disposed around the first gate structure 530 and coupled to the first set of channels 534 and forming a second source/drain epitaxial (S/D EPI) structure 590b disposed around the second gate structure 540 and coupled to the second set of channels 544. In some aspects, the source/drain structures 590a and 590b may be formed by an epitaxial growing process.

It will be appreciated that the foregoing example processes were provided in a summary manner to merely illustrate some of the aspects disclosed. In some advantageous aspects, it will be appreciated that the various aspects disclosed include the benefit that after preparation of the incoming wafer (e.g., nanosheet wafer 505), conventional GAA fabrication processing can be performed in the first region 510 (e.g., core, logic, and the like) and that the second region 520 (e.g., high-voltage, IO, and the like) can be fabricated by the same conventional GAA processes. It will be appreciated that the additional sacrificial portions (e.g., Ge implanted Si sacrificial portions 521 and 523) will be removed along with the sacrificial gate layers (e.g., SiGe layers) which results in the increased spacing between the channels. In some aspects, an additional mask step can be used to form a thicker gate dielectric (e.g., gate dielectric 146) in the GAA devices of the second region. For example, as discussed in relation to FIG. 1, the gate dielectric 146 may have an additional dielectric layer (e.g., middle dielectric layer 146b) formed in the second region.

For example, for both the first region 510 and the second region 520, an interfacial oxide layer (e.g., 136a, 146a) can be formed from thermal oxidation of the silicon channel. The first region 510 can be masked and in the second region 520 an additional dielectric layer can be grown (e.g., a middle dielectric layer 146b) which is thicker than interfacial oxide layer (e.g., 136a, 146a) and can be formed in the increased space between the channels. Conventional processing can continue in both the first and second regions with the high-K dielectric being deposited and the gate metal (work-function metal) (e.g., 132, 142) is filled in where the sacrificial gate layers and additional sacrificial portions were removed to produce the gate structure 130 in the first region and the second gate structure 140 in the second region (as illustrated in FIGS. 1 and 4A). The increased gate spacing of the gate structure 140 relative to the gate structure 130, supports the thicker dielectric and higher voltage applications in the second region.

At this stage, one or more of a front end of line (FEOL) process, a middle of line (MOL) process, or back end of line (BEOL) process may be performed in order to form a plurality of layers of metallization structures. In some aspects, the FEOL process may correspond to forming conductive vias or contacts on the GAA devices in order to prepare the electrical components for interconnection. In some aspects, the MOL process may be performed after the FEOL process and may correspond to forming conductive vias and conductive lines for local interconnections among neighboring electrical components. In some aspects, the BEOL process may be performed after the MOL process and may correspond to forming conductive vias and conductive lines for interconnections among groups of electrical components. In some aspects, the MOL process may be omitted, and the local interconnections may be formed based on the FEOL process, the BEOL process, or both.

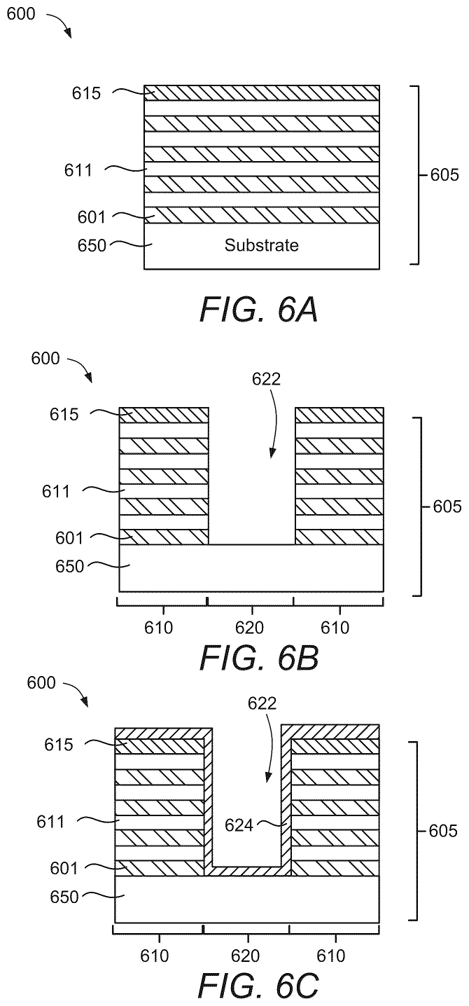

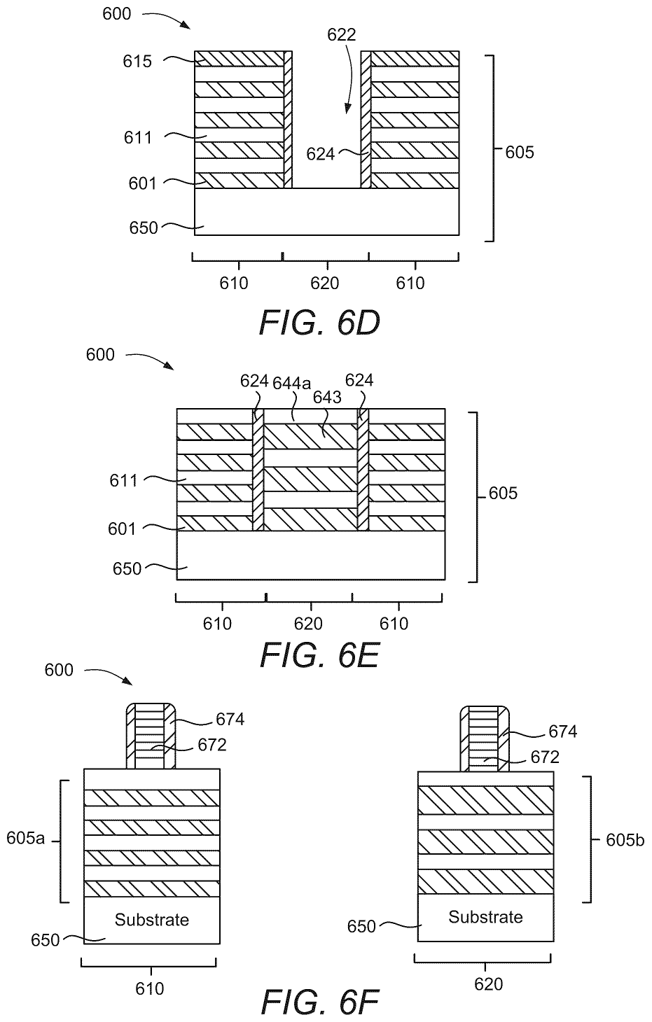

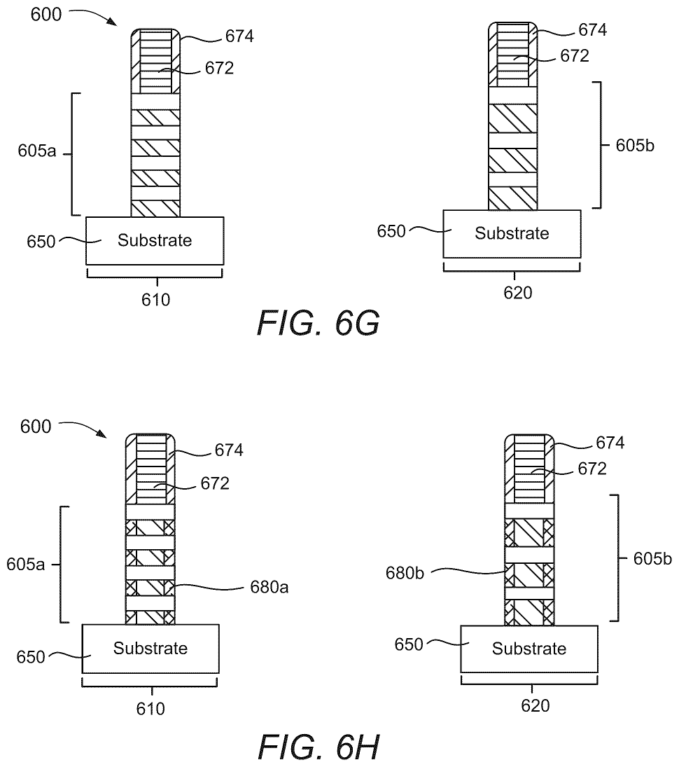

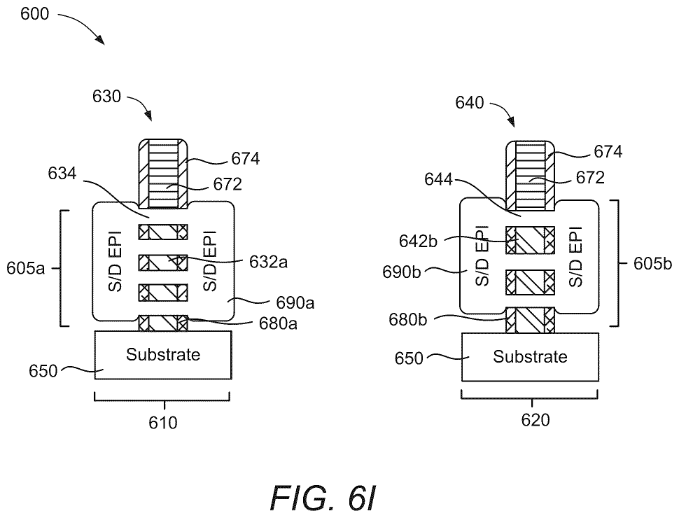

FIGS. 6A-6I illustrate an example partial method for manufacturing a semiconductor device (e.g., the semiconductor device 200 in FIG. 2), according to aspects of the disclosure.

As shown in FIG. 6A, a semiconductor device 600 is formed in part by the fabrication process with a nanosheet wafer 605 having a substrate 650, a first plurality of sacrificial gate layers 601 and a first plurality of nanosheet layers 611. A hard mask 615 (e.g., silicon nitride) is disposed on the nanosheet wafer 605. In some aspects, the first plurality of nanosheet layers 611 comprises Si. In some aspects, the substrate 650 includes Si, Ge, As, or any combination thereof. In some aspects, the first plurality of sacrificial gate layers 601 may be SiGe.

As shown in FIG. 6B, the semiconductor device 600 fabrication process continues at this stage with the hard mask 615 being opened to allow for the formation of a cavity 622 through the first plurality of sacrificial gate layers 601 and first plurality of nanosheet layers 611. The cavity extends to the substrate 650 and is formed in a second region 620. The remaining portions of the nanosheet wafer 605 that are unchanged define a first region 610.

As shown in FIG. 6C, the semiconductor device 600 fabrication process continues with the nanosheet wafer 605 having the cavity 622 extending through the first plurality of sacrificial gate layers 601 and the first plurality of nanosheet layers 611. The cavity extends to the substrate 650 and is formed in a second region 620. At this stage of the process, a spacer 624 (e.g., silicon nitride) is deposited in the cavity 622 in the second region 620. In some aspects, the spacer 624 extends over the substrate 650 in the bottom of the cavity 622 in the second region and over the hard mask 615 in the first region.

As shown in FIG. 6D, the semiconductor device 600 fabrication process continues with the nanosheet wafer 605 having the cavity 622 extending through the first plurality of sacrificial gate layers 601 and the first plurality of nanosheet layers 611, with a spacer 624 deposited in the cavity. At this stage of the process, an etching process is performed to remove the portions of the spacer 624 in the bottom of the cavity 622 in the second region and over the hard mask 615 in the first region. The spacer 624 remains on sidewalls of the nanosheet wafer 605 that define the cavity 622 and provides isolation between the first region 610 and the second region 620.

As shown in FIG. 6E, the semiconductor device 600 fabrication process continues with the nanosheet wafer 605 having the first plurality of sacrificial gate layers 601 and the first plurality of nanosheet layers 611 disposed on substrate 650. The spacer 624 separates the first region 610 from the second region 620. At this stage of the process, a second plurality of nanosheet layers 644a and a second plurality of sacrificial gate layers 643 are formed in the second region 620 between the spacer 624 on the sidewalls. The second plurality of sacrificial gate layers 643 are each thicker than the first plurality of sacrificial gate layers 601 in the first region 610. Accordingly, it will be appreciated that the number of the second plurality of nanosheet layers 644a in the second region will be less than the number of the first plurality of nanosheet layers 611 in the first region. The process continues to planarize and remove (e.g., chemical-mechanical polishing (CMP) process) the hard mask 615.

The fabrication process of FIGS. 6A-6E forms an incoming nanosheet wafer 605. It will be appreciated that the incoming nanosheet wafer 605 has two distinct regions, the first region 610 that has a first plurality of sacrificial gate layers 601 which are thinner and first plurality of nanosheet layers 611 and a second region has a second plurality of sacrificial gate layers 643 which are thicker and results in an increased pitch between the second plurality of nanosheet layers 644a in the second region. The incoming nanosheet wafer 605 will be used in the further processing discussed below.

As shown in FIG. 6F, the semiconductor device 600 fabrication process continues with a first gate stack 605a on substrate 650. The first gate stack 605a has a gate polysilicon 672 and outer spacer 674 formed in the first region 610. A second gate stack 605b, on substrate 650, has a gate polysilicon 672 and outer spacer 674 formed in the second region 620. The second gate stack 605b in the second region 620 has the thicker sacrificial gate layers than the first gate stack 605a in the first region 610, which are derived from the incoming nanosheet wafer 605, discussed above. The gate polysilicon 672 and outer spacer 674 can be formed using conventional processes in both the first region 610 and the second region 620.

As shown in FIG. 6G, the semiconductor device 600 fabrication process continues with first gate stack 605a on substrate 650, with the gate polysilicon 672 and outer spacer 674 formed thereon, in the first region 610. The second gate stack 605b, on substrate 650, has a gate polysilicon 672 and outer spacer 674 formed in the second region 620. At this stage, a source/drain (S/D) recess process is performed to remove excess wafer material from the S/D regions adjacent the first gate stack 605a and the second gate stack 605b. The source/drain (S/D) recess process may be performed using conventional fabrication processes for GAA devices.

As shown in FIG. 6H, the semiconductor device 600 fabrication process continues with first gate stack 605a on substrate 650, with the gate polysilicon 672 and outer spacer 674 formed thereon, in the first region 610. The second gate stack 605b, on substrate 650, has a gate polysilicon 672 and outer spacer 674 formed in the second region 620. At this stage, the process continues with the inner spacer formation. The sacrificial gate layers of the first gate stack 605a and the second gate stack 605b are indented to allow room for encapsulation of the sacrificial gate layers with a dielectric that forms the inner spacers. For the GAA devices in the first region 610, there are four inner spacers 680a formed. For the GAA devices in the second region 620, there are three inner spacers 680b formed. It will be appreciated that the second gate stack 605b in the second region 620 has an increased height of inner spacers 680b relative to the inner spacers 680a. The increased spacing or pitch between the nanosheet layers in the second gate stack 605b in the second region 620 provides for forming the thicker gate dielectric in the second region in later processing, as illustrated and discussed herein including in relation to the example aspects of FIG. 2.

As shown in FIG. 6I, the semiconductor device 600 fabrication process continues with a first gate structure 630 in the first region 610 which includes the gate polysilicon 672 and outer spacer 674, the first gate stack 605a which includes first set of channels 634 (formed from the nanosheets, discussed above) and sacrificial gate layers 632a with inner spacers 680a. A second gate structure 640 is in the second region 620 which includes the gate polysilicon 672 and outer spacer 674, a second gate stack 605b which includes a second set of channels 644 (formed from the second plurality of nanosheet layers 644a) and sacrificial gate layers 642b with inner spacers 680b. At this stage, the process continues with forming a first S/D EPI structure 690a disposed around the first gate stack 605a and coupled to the first set of channels 634 and forming a second source/drain epitaxial (S/D EPI) structure 690b disposed around the second gate stack 605b and coupled to the second set of channels 644. In some aspects, the S/D EPI structures 690a and 690b may be formed by an epitaxial growing process.

It will be appreciated that the foregoing example processes were provided in a summary manner to merely illustrate some of the aspects disclosed. In some advantageous aspects, it will be appreciated that the various aspects disclosed include the benefit that after preparation of the incoming wafer (e.g., nanosheet wafer 605), conventional GAA fabrication processing can be performed in the first region (e.g., core, logic, and the like) and that the second region (e.g., high-voltage, IO, and the like) can be fabricated by the same conventional GAA processes. After the sacrificial gate layers (e.g., SiGe layers) are removed there will be an additional mask step used to form a thicker gate dielectric (e.g., middle dielectric layer 246b) in the GAA devices of the second region. For example, as discussed in relation to FIG. 2, the second set of gate dielectrics 246 may have an additional dielectric layer (e.g., middle dielectric layer 246b) formed in the second region. For example, for both the first and second regions an interfacial oxide layer (e.g., 236a and 246a of FIG. 2) can be formed from thermal oxidation of the silicon channel. The first region can be masked and in the second region an additional dielectric layer (e.g., middle dielectric layer 246b of FIG. 2) can be grown which is thicker than the interfacial oxide layer and can be formed in the increased space between the channels. Afterwards, the fabrication process can continue in both the first region 610 and second region 620 with the high-K dielectric (e.g., 236c. 246c) being deposited and the gate metal (e.g., 232, 242) being filled in where the sacrificial gate layers and additional sacrificial portions were removed to produce the gate structure 230 in the first region and the second gate structure 240 in the second region (as illustrated in FIGS. 2 and 4B). The increased gate spacing of the gate structure 240 relative to the gate structure 230, supports the thicker dielectric and higher voltage applications in the second region.

At this stage, one or more of a front end of line (FEOL) process, a middle of line (MOL) process, or back end of line (BEOL) process may be performed in order to form a plurality of layers of metallization structures. In some aspects, the FEOL process may correspond to forming conductive vias or contacts on the GAA devices in order to prepare the electrical components for interconnection. In some aspects, the MOL process may be performed after the FEOL process and may correspond to forming conductive vias and conductive lines for local interconnections among neighboring electrical components. In some aspects, the BEOL process may be performed after the MOL process and may correspond to forming conductive vias and conductive lines for interconnections among groups of electrical components. In some aspects, the MOL process may be omitted, and the local interconnections may be formed based on the FEOL process, the BEOL process, or both.

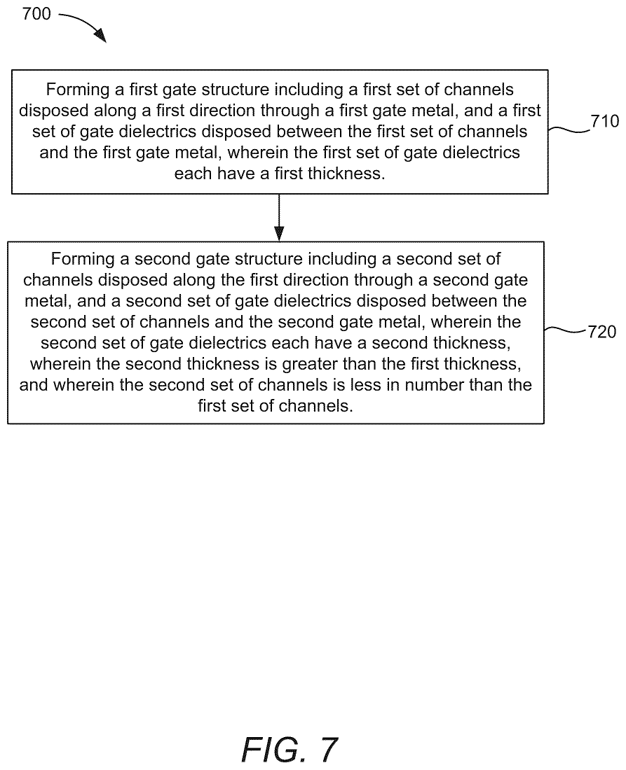

FIG. 7 illustrates a method 700 for manufacturing a semiconductor device (such as the semiconductor device 100 in FIG. 1 and semiconductor device 200 in FIG. 2), according to aspects of the disclosure.

At operation 710, a first gate structure (e.g., gate structures 130/230) is formed including a first set of channels (e.g., 134/234) disposed along a first direction through a first gate metal (e.g., 132/232), and a first set of gate dielectrics (e.g., 136/236) disposed between the first set of channels (e.g., 134/234) and the first gate metal (e.g., 132/232). The first set of gate dielectrics (e.g., 136/236) each have a first thickness.

At operation 720, a second gate structure (e.g., the gate structure 140/240) is formed. The second gate structure (e.g., 140/240) includes a second set of channels (e.g., 144/244) disposed along the first direction through a second gate metal (e.g., 142/242), and a second set of gate dielectrics (e.g., 146/246) disposed between the second set of channels (e.g., 144/244) and the second gate metal (e.g., 142/242). The second set of gate dielectrics (e.g., 146/246) each have a second thickness. Further, the second thickness is greater than the first thickness and the second set of channels is less in number than the first set of channels.

In some aspects, the fabrication methods may incorporate additional fabrication processes as illustrated with reference to FIGS. 5A-5K. In some aspects, the method may further include fabricating a wafer (e.g., nanosheet wafer 505) for forming at least part of the semiconductor device. In some aspects, a first plurality of nanosheet layers are formed in a first region (e.g., nanosheet layers 511, 512, 513 and 514) corresponding to the first set of channels. In some aspects, a first plurality of sacrificial gate layers (501, 502, 503 and 504) are formed and disposed in an alternating layer pattern with the first plurality of nanosheet layers. In some aspects, at least one of the a first plurality of nanosheet layers (e.g., 511 and 513) is infused with germanium to form a sacrificial portion (e.g., 521 and 523) disposed between adjacent sacrificial gate layers (e.g., 501 and 502 for 521 and 503 and 504 for 523) of the first plurality of sacrificial gate layers in a second region (e.g., 520). As discussed herein, the later processing will provide for the reduced number of channels, increased channel spacing and increased gate dielectric thickness and the second region,

In some aspects, the fabrication methods may incorporate additional fabrication processes as illustrated with reference to FIGS. FIGS. 6A-6I. In some aspects, the method may further include fabricating a wafer for forming at least part of the semiconductor device. In some aspects the wafer (e.g., nanosheet wafers 605) can be fabricated to include a first plurality of nanosheet layers (e.g., 611) in a first region corresponding to the first set of channels and a first plurality of sacrificial gate layers (e.g., 601) disposed in an alternating layer pattern with the first plurality of nanosheet layers. In some aspects the wafer (e.g., nanosheet wafers 605) can be fabricated to include a second plurality of nanosheet layers (e.g., 644a) in a second region (e.g., 620) corresponding to the second set of channels and a second plurality of sacrificial gate layers (e.g., 643) disposed in an alternating layer pattern with the second plurality of nanosheet layers. As discussed herein, the later processing will provide for the reduced number of channels, increased channel spacing and increased gate dielectric thickness and the second region.

In some aspects (see, e.g., FIGS. 5A-5K), the second region includes one or more sacrificial portions (e.g., 521/523) of the nanosheet layer that has been implanted with Ge, so that the one or more sacrificial portions will be generally homogenous with the adjacent sacrificial gate layers to provide for increased spacing/pitch between the nanosheet layers (which ultimately form the channels) in the second region.

In some aspects (see, e.g., FIGS. 6A-6I), the second region includes a reduced number of nanosheet layers formed on sacrificial gate layers that are thicker than the sacrificial gate layers in the first region to provide for increased spacing/pitch between the nanosheet layers (which ultimately form the channels) in the second region.

As will be appreciated, technical advantages of the method 700 include providing for different device characteristics (e.g., different gate dielectric thickness, channel count), in the different regions on a common wafer. As discussed herein, the first region can be configured for core logic, high speed, and the like GAA devices and the second region can be configured for high-voltage, IO, and the like GAA devices. As such, the complexity of the manufacturing process may be reduced, the cost of manufacturing the semiconductor device may be reduced, the yield rate of the manufacturing process may be increased, and/or the throughput of the manufacturing process may be increased.

It will be appreciated that the foregoing fabrication process was provided merely as a general illustration of some of the aspects of the disclosure and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations.

The foregoing disclosed devices and functionalities may be designed and stored in computer files (e.g., register-transfer level (RTL), Geometric Data Stream (GDS), Gerber, and the like) stored on computer-readable media. Some or all such files may be provided to fabrication handlers who fabricate devices based on such files. Resulting products may include various components, including semiconductor wafers that are then cut into semiconductor die and packaged into semiconductor packages, integrated devices, package on package devices, system-on-chip devices, and the like, which may then be employed in the various devices described herein.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

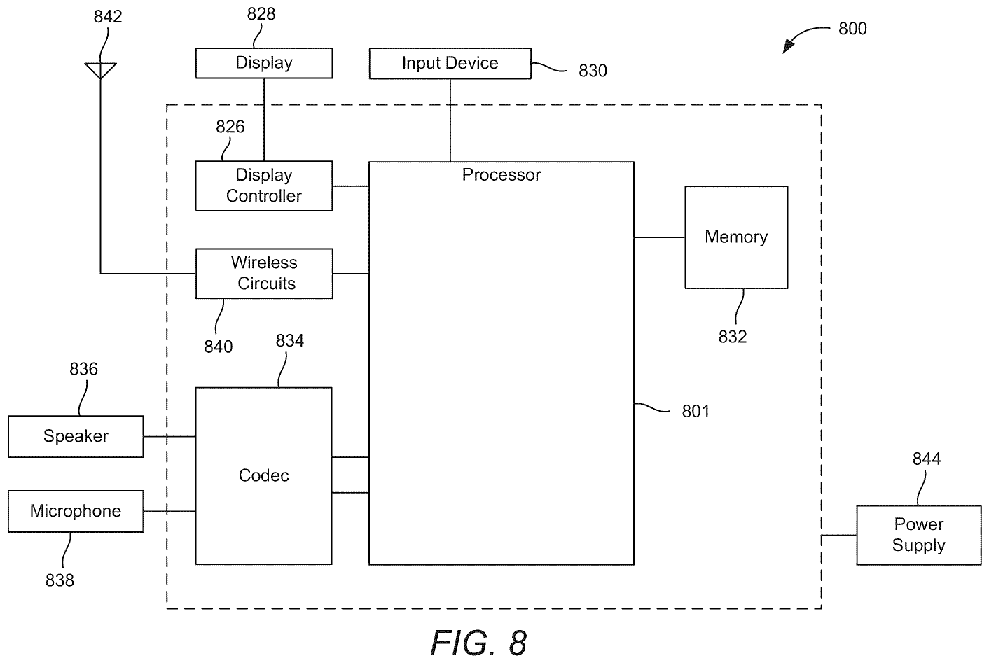

FIG. 8 illustrates a mobile device 800, according to aspects of the disclosure. In some aspects, the mobile device 800 may be implemented by including one or more ICs including semiconductor devices disclosed and manufactured based on the examples described in this disclosure (e.g., SOC products including logic, memory, and/or analog aspects).

In some aspects, mobile device 800 may be configured as a wireless communication device. As shown, mobile device 800 includes processor 801. Processor 801 may be communicatively coupled to memory 832 over a link, which may be a die-to-die or chip-to-chip link. Mobile device 800 also includes display 828 and display controller 826, with display controller 826 coupled to processor 801 and to display 828. The mobile device 800 may include input device 830 (e.g., physical, or virtual keyboard), power supply 844 (e.g., battery), speaker 836, microphone 838, and wireless antenna 842. In some aspects, the power supply 844 may directly or indirectly provide the supply voltage for operating some or all of the components of the mobile device 800.

In some aspects, FIG. 8 may include coder/decoder (CODEC) 834 (e.g., an audio and/or voice CODEC) coupled to processor 801; speaker 836 and microphone 838 coupled to CODEC 834; and wireless circuits 840 (which may include a modem, RF circuitry, filters, etc.) coupled to wireless antenna 842 and to processor 801.

In some aspects, one or more of processor 801, display controller 826, memory 832, CODEC 834, and wireless circuits 840 may include one or more ICs including semiconductor devices manufactured according to the examples described in this disclosure.

It should be noted that although FIG. 8 depicts a mobile device 800, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

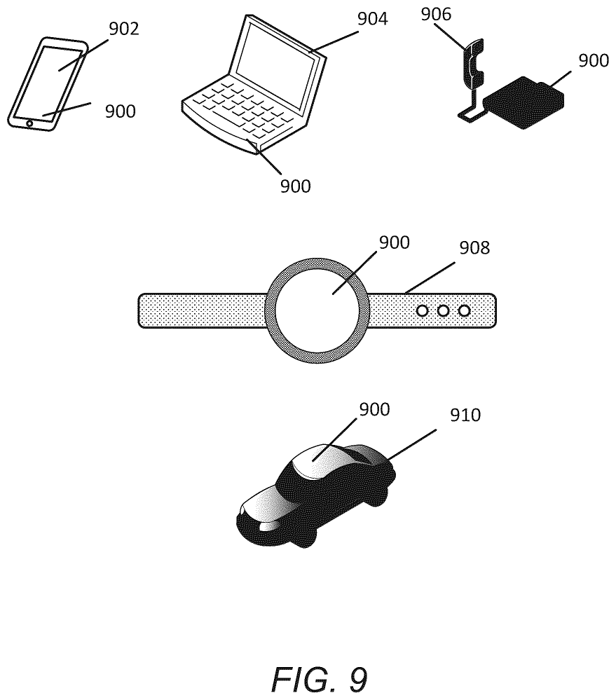

FIG. 9 illustrates various electronic devices that may be integrated with any of the aforementioned devices, semiconductor devices, integrated circuit (IC) packages, integrated circuit (IC) devices, semiconductor devices, integrated circuits, electronic components, interposer packages, package-on-package (POP), System in Package (SiP), or System on Chip (SoC). For example, a mobile phone device 902, a laptop computer device 904, a fixed location terminal device 906, a wearable device 908, or automotive vehicle 910 may include a semiconductor device 900 (e.g., semiconductor device 100, 200, 500 and 600) as described herein. The devices 902, 904, 906 and 908 and the vehicle 910 illustrated in FIG. 9 are merely exemplary. Other apparatuses or devices may also feature the semiconductor device 900 including, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1 through 9 may be rearranged and/or combined into a single component, process, feature, or function or incorporated in several components, processes, or functions. Additional elements, components, processes, and/or functions may also be added without departing from the disclosure. In some implementations, FIGS. 1 through 9 and the corresponding description may be used to manufacture, create, provide, and/or produce integrated devices. In some implementations, a device may include a die, an integrated device, a die package, an IC, a device package, an IC package, a wafer, a semiconductor device, a system in package (SiP), a system on chip (SoC), a package on package (POP) device, and the like.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. UEs can be embodied by any of a number of types of devices including but not limited to printed circuit (PC) cards, compact flash devices, external or internal modems, wireless or wireline phones, smartphones, tablets, consumer tracking devices, asset tags, and so on.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth® (BT), BT Low Energy (BLE), IEEE 802.11 (WiFi), and IEEE 802.15.4 (Zigbee/Thread) or other protocols that may be used in a wireless communications network or a data communications network.

Nothing stated or illustrated depicted in this application is intended to dedicate any component, action, feature, benefit, advantage, or equivalent to the public, regardless of whether the component, action, feature, benefit, advantage, or the equivalent is recited in the claims.

Further, those of skill in the art will appreciate that the various illustrative logical blocks, modules, circuits, and algorithm actions described in connection with the examples disclosed herein may be implemented as electronic hardware, computer software, or combinations of both. To clearly illustrate this interchangeability of hardware and software, various illustrative components, blocks, modules, circuits, and actions have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

Although some aspects have been described in connection with a device, it goes without saying that these aspects also constitute a description of the corresponding method, and so a block or a component of a device should also be understood as a corresponding method action or as a feature of a method action. Analogously thereto, aspects described in connection with or as a method action also constitute a description of a corresponding block or detail or feature of a corresponding device. Some or all of the method actions can be performed by a hardware apparatus (or using a hardware apparatus), such as, for example, a microprocessor, a programmable computer, or an electronic circuit. In some examples, some or a plurality of the most important method actions can be performed by such an apparatus.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory) aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses.

Clause 1. An apparatus comprising a semiconductor device wherein the semiconductor device comprises: a first gate structure including a first set of channels disposed along a first direction through a first gate metal, and a first set of gate dielectrics disposed between the first set of channels and the first gate metal, wherein the first set of gate dielectrics each have a first thickness; and a second gate structure including a second set of channels disposed along the first direction through a second gate metal, and a second set of gate dielectrics disposed between the second set of channels and the second gate metal, wherein the second set of gate dielectrics each have a second thickness, wherein the second thickness is greater than the first thickness, and wherein the second set of channels is less in number than the first set of channels.

Clause 2. The apparatus of clause 1, wherein the first thickness of the first set of gate dielectrics is in a range of 0.8 to 1.5 nanometers (nm), and wherein the second thickness of the second set of gate dielectrics is in a range of 2.5 to 3.5 nm.

Clause 3. The apparatus of any of clauses 1 to 2, wherein the second set of gate dielectrics each have at least one additional dielectric layer than the first set of gate dielectrics.

Clause 4. The apparatus of clause 3, wherein the at least one additional dielectric layer is a different material than other dielectric layers of the second set of gate dielectrics.

Clause 5. The apparatus of clause 4, wherein the second set of gate dielectrics each comprise: an interfacial oxide layer; a high dielectric constant (high-K) dielectric; and a middle dielectric layer disposed between the interfacial oxide layer and the high-K dielectric, and wherein the first set of gate dielectrics each comprise: the interfacial oxide layer; and the high-K dielectric.

Clause 6. The apparatus of any of clauses 1 to 5, wherein a second distance between channels of the second set of channels is greater than a first distance between channels of the first set of channels.

Clause 7. The apparatus of clause 6, wherein the first distance is in a range of 8 to 12 nanometers (nm), and wherein the second distance is in a range of 20 to 28 nm.

Clause 8. The apparatus of clause 6, wherein the first distance is in a range of 8 to 12 nanometers (nm), and wherein the second distance is in a range of 12 to 18 nm.

Clause 9. The apparatus of any of clauses 1 to 8, wherein the first gate structure and the second gate structure are disposed on a substrate.

Clause 10. The apparatus of any of clauses 1 to 9, wherein a first channel of the first set of channels and a second channel of the second set of channels are coplanar along the first direction.

Clause 11. The apparatus of any of clauses 1 to 10, wherein the first set of channels and the second set of channels are nanosheets.

Clause 12. The apparatus of any of clauses 1 to 11, wherein the first gate structure is in a first region of the semiconductor device and the second gate structure is in a second region of the semiconductor device.

Clause 13. The apparatus of clause 12, further comprising: a first source/drain structure disposed on opposite sides of the first gate structure coupled to the first set of channels; and a second source/drain structure disposed on opposite sides of the second gate structure coupled to the second set of channels.

Clause 14. The apparatus of clause 13, wherein the first gate structure and the first source/drain structure are part of a first gate-all-around (GAA) device in the first region and the second gate structure and the second source/drain structure are part of a second GAA device in the second region.

Clause 15. The apparatus of any of clauses 1 to 14, wherein the first set of channels has twice a number of channels as the second set of channels.

Clause 16. The apparatus of any of clauses 1 to 15, wherein each channel of the second set of channels is coplanar in the first direction with a corresponding channel of the first set of channels.

Clause 17. The apparatus of any of clauses 1 to 15, wherein at least one channel of the second set of channels is not coplanar in the first direction with any channel of the first set of channels.

Clause 18. The apparatus of any of clauses 1 to 17, wherein the apparatus comprises at least one of a music player, a video player, an entertainment unit, a navigation device, a communications device, a mobile device, a mobile phone, a smartphone, a personal digital assistant, a fixed location terminal, a tablet computer, a computer, a wearable device, an Internet of Things (IoT) device, a laptop computer, a server, an access point, a base station, or a device in an automotive vehicle.

Clause 19. A method of manufacturing a semiconductor device, comprising: forming a first gate structure including a first set of channels disposed along a first direction through a first gate metal, and a first set of gate dielectrics disposed between the first set of channels and the first gate metal, wherein the first set of gate dielectrics each have a first thickness; and forming a second gate structure including a second set of channels disposed along the first direction through a second gate metal, and a second set of gate dielectrics disposed between the second set of channels and the second gate metal, wherein the second set of gate dielectrics each have a second thickness, wherein the second thickness is greater than the first thickness, and wherein the second set of channels is less in number than the first set of channels.

Clause 20. The method of clause 19, further comprising processing a wafer for forming at least part of the semiconductor device, wherein processing the wafer comprises: forming a first plurality of nanosheet layers; forming a first plurality of sacrificial gate layers disposed in an alternating layer pattern with the first plurality of nanosheet layers; and infusing at least one of the first plurality of nanosheet layers with germanium to form a sacrificial portion disposed between adjacent sacrificial gate layers of the first plurality of sacrificial gate layers.

Clause 21. The method of clause 19, further comprising processing a wafer for forming at least part of the semiconductor device, wherein processing the wafer comprises: forming a first plurality of nanosheet layers in a first region corresponding to the first set of channels; forming a first plurality of sacrificial gate layers disposed in an alternating layer pattern with the first plurality of nanosheet layers; forming a second plurality of nanosheet layers in a second region corresponding to the second set of channels; and forming a second plurality of sacrificial gate layers disposed in an alternating layer pattern with the second plurality of nanosheet layers.

Clause 22. The method of any of clauses 19 to 21, wherein the second set of gate dielectrics each have at least one additional dielectric layer than the first set of gate dielectrics.

Clause 23. The method of clause 22, wherein the at least one additional dielectric layer is a different material than other dielectric layers of the second set of gate dielectrics.

Clause 24. The method of clause 23, wherein forming the second set of gate dielectrics comprises: forming an interfacial oxide layer in a second region; forming a high dielectric constant (high-K) dielectric in the second region; and forming a middle dielectric layer disposed between the interfacial oxide layer and the high-K dielectric in the second region, and wherein forming the first set of gate dielectrics comprises: forming the interfacial oxide layer in a first region; and forming the high-K dielectric in the first region.

Clause 25. The method of any of clauses 19 to 24, wherein a second distance between channels of the second set of channels is greater than a first distance between channels of the first set of channels.

Clause 26. The method of any of clauses 19 to 25, wherein the first set of channels and the second set of channels are nanosheets.

Clause 27. The method of any of clauses 19 to 26, wherein the first gate structure is in a first region of the semiconductor device and the second gate structure is in a second region of the semiconductor device.

Clause 28. The method of clause 27, further comprising: forming a first source/drain structure disposed on opposite sides of the first gate structure coupled to the first set of channels; and forming a second source/drain structure disposed on opposite sides of the second gate structure coupled to the second set of channels.

Clause 29. The method of clause 28, wherein the first gate structure and the first source/drain structure are part of a first gate-all-around (GAA) device in the first region and the second gate structure and the second source/drain structure are part of a second GAA device in the second region.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Those skilled in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Nothing stated or illustrated depicted in this application is intended to dedicate any component, action, feature, benefit, advantage, or equivalent to the public, regardless of whether the component, action, feature, benefit, advantage, or the equivalent is recited in the claims.

It should furthermore be noted that methods, systems, and apparatus disclosed in the description or in the claims can be implemented by a device comprising means for performing the respective actions and/or functionalities of the methods disclosed. Furthermore, While the foregoing disclosure shows illustrative aspects of the disclosure, it should be noted that various changes and modifications could be made herein without departing from the scope of the disclosure as defined by the appended claims. For example, the functions, steps and/or actions of the method claims in accordance with the aspects of the disclosure described herein need not be performed in any particular order.

Further, no component, function, action, or instruction described or claimed herein should be construed as critical or essential unless explicitly described as such. Furthermore, as used herein, the terms “set,” “group,” and the like are intended to include one or more items and may be used interchangeably with “at least one,” “one or more,” and the like. Also, as used herein, the terms “has,” “have,” “having,” and the like are intended to be open-ended terms that do not limit an element that they modify (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”) or the alternatives are mutually exclusive (e.g., “one or more” should not be interpreted as “one and more”). Furthermore, although components, functions, actions, and instructions may be described or claimed in the singular, the plural is contemplated unless limitation to the singular is explicitly stated. Accordingly, as used herein, the articles “a,” “an,” “the,” and “said” are intended to include one or more items and may be used interchangeably with “at least one,” “one or more,” and the like. Additionally, as used herein, the terms “at least one” and “one or more” encompass “one” component, function, action, or instruction performing or capable of performing a described or claimed functionality and also “two or more” components, functions, actions, or instructions performing or capable of performing a described or claimed functionality in combination. In some examples, an individual action can be subdivided into one or more sub-actions or contain one or more sub-actions. Such sub-actions can be contained in the disclosure of the individual action and be part of the disclosure of the individual action.

What is claimed is:

1. An apparatus comprising a semiconductor device wherein the semiconductor device comprises:
a first gate structure including a first set of channels disposed along a first direction through a first gate metal, and a first set of gate dielectrics disposed between the first set of channels and the first gate metal, wherein the first set of gate dielectrics each have a first thickness; and
a second gate structure including a second set of channels disposed along the first direction through a second gate metal, and a second set of gate dielectrics disposed between the second set of channels and the second gate metal, wherein the second set of gate dielectrics each have a second thickness,
wherein the second thickness is greater than the first thickness, and
wherein the second set of channels is less in number than the first set of channels.

2. The apparatus of claim 1, wherein the first thickness of the first set of gate dielectrics is in a range of 0.8 to 1.5 nanometers (nm), and wherein the second thickness of the second set of gate dielectrics is in a range of 2.5 to 3.5 nm.

3. The apparatus of claim 1, wherein the second set of gate dielectrics each have at least one additional dielectric layer than the first set of gate dielectrics.

4. The apparatus of claim 3, wherein the at least one additional dielectric layer is a different material than other dielectric layers of the second set of gate dielectrics.

5. The apparatus of claim 4, wherein the second set of gate dielectrics each comprise:
an interfacial oxide layer;
a high dielectric constant (high-K) dielectric; and
a middle dielectric layer disposed between the interfacial oxide layer and the high-K dielectric, and
wherein the first set of gate dielectrics each comprise:
the interfacial oxide layer; and
the high-K dielectric.

6. The apparatus of claim 1, wherein a second distance between channels of the second set of channels is greater than a first distance between channels of the first set of channels.

7. The apparatus of claim 6, wherein the first distance is in a range of 8 to 12 nanometers (nm), and wherein the second distance is in a range of 20 to 28 nm.

8. The apparatus of claim 6, wherein the first distance is in a range of 8 to 12 nanometers (nm), and wherein the second distance is in a range of 12 to 18 nm.

9. The apparatus of claim 1, wherein the first gate structure and the second gate structure are disposed on a substrate.

10. The apparatus of claim 1, wherein a first channel of the first set of channels and a second channel of the second set of channels are coplanar along the first direction.

11. The apparatus of claim 1, wherein the first set of channels and the second set of channels are nanosheets.

12. The apparatus of claim 1, wherein the first gate structure is in a first region of the semiconductor device and the second gate structure is in a second region of the semiconductor device.

13. The apparatus of claim 12, further comprising:
a first source/drain structure disposed on opposite sides of the first gate structure coupled to the first set of channels; and
a second source/drain structure disposed on opposite sides of the second gate structure coupled to the second set of channels.

14. The apparatus of claim 13, wherein the first gate structure and the first source/drain structure are part of a first gate-all-around (GAA) device in the first region and the second gate structure and the second source/drain structure are part of a second GAA device in the second region.

15. The apparatus of claim 1, wherein the first set of channels has twice a number of channels as the second set of channels.

16. The apparatus of claim 1, wherein each channel of the second set of channels is coplanar in the first direction with a corresponding channel of the first set of channels.

17. The apparatus of claim 1, wherein at least one channel of the second set of channels is not coplanar in the first direction with any channel of the first set of channels.

18. The apparatus of claim 1, wherein the apparatus comprises at least one of a music player, a video player, an entertainment unit, a navigation device, a communications device, a mobile device, a mobile phone, a smartphone, a personal digital assistant, a fixed location terminal, a tablet computer, a computer, a wearable device, an Internet of Things (IoT) device, a laptop computer, a server, an access point, a base station, or a device in an automotive vehicle.

19. A method of manufacturing a semiconductor device, comprising:
forming a first gate structure including a first set of channels disposed along a first direction through a first gate metal, and a first set of gate dielectrics disposed between the first set of channels and the first gate metal, wherein the first set of gate dielectrics each have a first thickness; and
forming a second gate structure including a second set of channels disposed along the first direction through a second gate metal, and a second set of gate dielectrics disposed between the second set of channels and the second gate metal, wherein the second set of gate dielectrics each have a second thickness,
wherein the second thickness is greater than the first thickness, and
wherein the second set of channels is less in number than the first set of channels.

20. The method of claim 19, further comprising processing a wafer for forming at least part of the semiconductor device, wherein processing the wafer comprises:
forming a first plurality of nanosheet layers;
forming a first plurality of sacrificial gate layers disposed in an alternating layer pattern with the first plurality of nanosheet layers; and
infusing at least one of the first plurality of nanosheet layers with germanium to form a sacrificial portion disposed between adjacent sacrificial gate layers of the first plurality of sacrificial gate layers.

21. The method of claim 19, further comprising processing a wafer for forming at least part of the semiconductor device, wherein processing the wafer comprises:
forming a first plurality of nanosheet layers in a first region corresponding to the first set of channels;
forming a first plurality of sacrificial gate layers disposed in an alternating layer pattern with the first plurality of nanosheet layers;
forming a second plurality of nanosheet layers in a second region corresponding to the second set of channels; and
forming a second plurality of sacrificial gate layers disposed in an alternating layer pattern with the second plurality of nanosheet layers.

22. The method of claim 19, wherein the second set of gate dielectrics each have at least one additional dielectric layer than the first set of gate dielectrics.

23. The method of claim 22, wherein the at least one additional dielectric layer is a different material than other dielectric layers of the second set of gate dielectrics.

24. The method of claim 23, wherein forming the second set of gate dielectrics comprises:
forming an interfacial oxide layer in a second region;
forming a high dielectric constant (high-K) dielectric in the second region; and
forming a middle dielectric layer disposed between the interfacial oxide layer and the high-K dielectric in the second region, and
wherein forming the first set of gate dielectrics comprises:
forming the interfacial oxide layer in a first region; and
forming the high-K dielectric in the first region.

25. The method of claim 19, wherein a second distance between channels of the second set of channels is greater than a first distance between channels of the first set of channels.

26. The method of claim 19, wherein the first set of channels and the second set of channels are nanosheets.

27. The method of claim 19, wherein the first gate structure is in a first region of the semiconductor device and the second gate structure is in a second region of the semiconductor device.

28. The method of claim 27, further comprising:
forming a first source/drain structure disposed on opposite sides of the first gate structure coupled to the first set of channels; and
forming a second source/drain structure disposed on opposite sides of the second gate structure coupled to the second set of channels.

29. The method of claim 28, wherein the first gate structure and the first source/drain structure are part of a first gate-all-around (GAA) device in the first region and the second gate structure and the second source/drain structure are part of a second GAA device in the second region.
